(19) United States
(12) Patent Application Publication
(10) Pub. No.: US 2025/0144969 A1
(43) Pub. Date: May 8, 2025

(54) CONTROL DEVICE FOR VEHICLE

(71) Applicant: HONDA MOTOR CO., LTD., Tokyo (JP)

(72) Inventors: Kazuki Yahata, Tokyo (JP); Koichi Horita, Tokyo (JP)

(21) Appl. No.: 18/932,650

(22) Filed: Oct. 31, 2024

(30) Foreign Application Priority Data
Nov. 7, 2023 (JP) 2023-189868

(51) Int. Cl. B60H 1/00; H05K 7/20

(52) U.S. Cl. CPC B60H 1/00271; B60H 1/00814; H05K 7/20945; H05K 7/20927

(57) ABSTRACT

A control device is cooled together with a drive train that is a cooling target part by a cooling circuit of a vehicle. The control device includes a first traveling controller configured to execute traveling control of reducing an operating load of a driver, and a second traveling controller configured to execute traveling control for reducing the operating load of the driver to a greater extent than in the first traveling controller. The control device reduces an output of the second traveling controller when a cooling load of the cooling target part is a predetermined load or more.

### CROSS-REFERENCE TO RELATED APPLICATION

Priority is claimed on Japanese Patent Application No. 2023-189868, filed Nov. 7, 2023, the content of which is incorporated herein by reference.

### BACKGROUND OF THE INVENTION

### Field of the Invention

The present invention relates to a control device for a vehicle.

### Description of Related Art

In recent years, research and development has been conducted that contributes to energy efficiency so that more people can have access to affordable, reliable, sustainable and advanced energy.

In the related art, there is known a vehicle including a first cooling water channel configured to cool a drive device, a second cooling water channel configured to cool a charger, a switching valve configured to switch between distribution of cooling water to the first cooling water channel or the second cooling water channel, and a control device configured to control the switching valve according to a state of the drive device and the charger (for example, see Japanese Unexamined Patent Application, First Publication No. 2021-48758).

### SUMMARY OF THE INVENTION

Incidentally, in this technology, the challenge is to improve cooling efficiency while appropriately cooling a plurality of devices and curbing increase in size of the apparatus configuration.

For example, as in the above-mentioned vehicle, if the cooling of each of the plurality of devices is selectively switched between and the plurality of devices are not cooled simultaneously, a problem occurs in that the cooling operation of the entire system is limited.

In addition, for example, by serially connecting cooling pipelines for a plurality of devices such as an on-vehicle charger, a power conversion apparatus for driving, and the like, in the case of a cooling mechanism configured to sequentially supply a cooling medium to the plurality of devices, there is a risk that the cooling capacity of the distribution channel of the cooling medium will be insufficient for devices on the downstream side.

An aspect of the present application is to suppress an increase in size of an apparatus configuration, while at the same time improving cooling efficiency by appropriately cooling a plurality of devices. Further, an aspect of the present application is to contribute to energy efficiency.

The present invention employs the following aspects.

(1) A control device for a vehicle (for example, a control device (10) in an embodiment) according to an aspect of the present invention includes a controller (for example, also functions as the control device (10) in the embodiment) cooled together with a cooling target part (for example, a drive train, a power storage device in the embodiment) by a cooling part (for example, a cooling circuit (21) in the embodiment) of a vehicle (for example, a vehicle (1) in the embodiment), the controller including a first controller (for example, a first traveling controller (10b) in the embodiment) configured to execute traveling control of reducing an operating load of a driver; and a second controller (for example, a second traveling controller (10c) in the embodiment) configured to execute traveling control for reducing the operating load of the driver to a greater extent than in the first controller, and an output of the second controller being reduced when the cooling load of the cooling target part is a predetermined load or more.

(2) In the control device for a vehicle according to the aspect of the above-mentioned (1), when reducing the output of the second controller, the controller may select a first state or a second state, which has a larger processing load than the first state and whose output reduction is resolved faster than the first state.

(3) In the control device for a vehicle according to the aspect of the above-mentioned (1) or (2), the controller and the cooling target part may need to be cooled while the vehicle is traveling.

(4) In the control device for a vehicle according to the aspect of the above-mentioned (3), wherein the controller and the cooling target part may be cooled in series by the cooling part.

(5) In the control device for a vehicle according to the aspect of the above-mentioned (1) or (2), the cooling target part may be a drive train (for example, a drive unit (24) in the embodiment) of the vehicle.

(6) In the control device for a vehicle according to the aspect of the above-mentioned (3), the controller may reduce the output of the second controller in at least any one of the following cases: when the vehicle is high speed traveling, when the vehicle is during towing traveling and when the vehicle is during climbing traveling.

(7) In the control device for a vehicle according to the aspect of the above-mentioned (6) dependent on the above-mentioned (2), the controller may reduce the output of the second controller with the second state when the vehicle is traveling on a highway.

(8) In the control device for a vehicle according to the aspect of the above-mentioned (6) or (7) dependent on the above-mentioned (2), the controller may reduce the output of the second controller with the first state when the vehicle is during towing traveling.

(9) In the control device for a vehicle according to the aspect of the above-mentioned (6) dependent on the above-mentioned (2), the controller may reduce the output of the second controller with the second state when the vehicle is high speed traveling, when the vehicle is during towing traveling or when the vehicle is during climbing traveling, and the controller may reduce the output of the second controller with the first state in at least any two or more of a plurality of cases: when the vehicle is high speed traveling, when the vehicle is during towing traveling and when the vehicle is during climbing traveling.

According to the aspect of the above-mentioned (1), by providing the controller that reduces the output of the second controller, which has a relatively large processing load when the cooling load of the cooling target part, which is cooled by the cooling part shared by the controller, is large, it is possible to efficiently and continuously cool the cooling target part and the controller while curbing increase in size of the cooling part. By maintaining the output of the first controller, which has a relatively small processing load, the increase in the operating load of the driver can be suppressed.

In the case of the aspect of the above-mentioned (2), the controller reduces the output of the second controller depending on the first or the second state, which differs in the magnitude of the processing load and the speed at which the output reduction is resolved, so that the output of the second controller can be reduced appropriately depending on the state of the vehicle.

In the case of the aspect of the above-mentioned (3), the cooling target part and the controller can be simultaneously cooled by the common cooling part during traveling of the vehicle.

In the case of the aspect of the above-mentioned (4), the cooling target part and the controller can be cooled simultaneously in series by the common cooling part, which makes it possible to reduce the complexity of the cooling part configuration compared to, for example, the case where the cooling target part and the controller are cooled in parallel.

In the case of the aspect of the above-mentioned (5), the drive train and the controller, which require cooling while the vehicle is traveling, can be cooled simultaneously by the common cooling part.

In the case of the aspect of the above-mentioned (6), by reducing the output of the second controller when the cooling load of the cooling target part increases according to the increase in the traveling load of the vehicle, it is possible to curb the cooling part becoming large and to efficiently and continuously cool the cooling target part and the controller.

In the case of the aspect of the above-mentioned (7), when the vehicle is traveling on a highway, the operational requirements of the second controller are greater, so the operating load of the driver can be appropriately reduced by reducing the output of the second controller in the second state more than in the first state.

In the case of the aspect of the above-mentioned (8), since the towing of the vehicle is unlikely to be terminated while traveling, and the traveling load and the cooling load of the controller are unlikely to decrease while traveling, the controller can be cooled appropriately by reducing the output of the second controller in the first state. In the case of the aspect of the above-mentioned (9), depending on the magnitude of the traveling load of the vehicle and the cooling load of the controller, the output of the second controller can be reduced stepwise or otherwise. When the cooling load of the controller is relatively small, the second state can be used to prioritize the speed of resolving the output reduction, and when the cooling load of the controller is relatively large, the first state can be used to prioritize cooling.

### BRIEF DESCRIPTION OF THE DRAWINGS

FIG. 1 is a block diagram showing a functional configuration of a vehicle of an embodiment of the present invention.

FIG. 2 is a configuration view of a temperature control system of the vehicle of the embodiment of the present invention.

FIG. 3 is a flowchart of an operation of a control device for a vehicle including the temperature control system of the embodiment of the present invention.

### DETAILED DESCRIPTION OF THE INVENTION

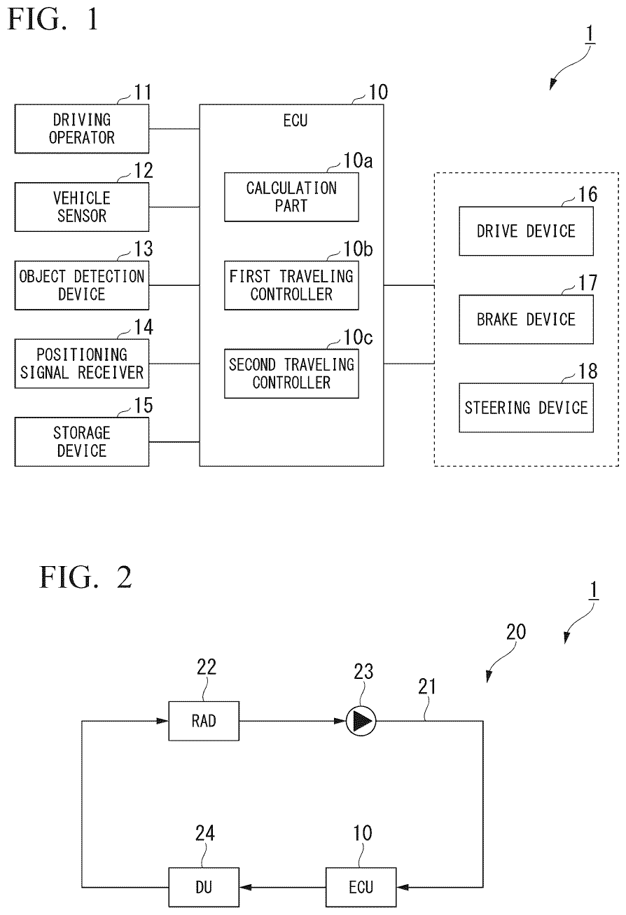

Hereinafter, a control device for a vehicle according to an embodiment of the present invention will be described with reference to the accompanying drawings. FIG. 1 is a block diagram showing a functional configuration of a vehicle 1 of the embodiment.

The vehicle 1 of the embodiment is, for example, an electric vehicle or the like that executes driving assistance and autonomous driving. The electric vehicle is an electric automobile, a hybrid vehicle, a fuel cell vehicle, or the like.

As shown in FIG. 1, the vehicle 1 includes, for example, a control device (ECU) 10, a driving operator 11, a vehicle sensor 12, an object detection device 13, a positioning signal receiver 14, a storage device 15, a drive device 16, a brake device 17, and a steering device 18.

The control device 10 is a software functional part that functions by executing a predetermined program using a processor such as a central processing unit (CPU) or the like. The software functional part is an electronic control unit (ECU) including a processor such as a CPU or the like, a read only memory (ROM) configured to store a program, a random access memory (RAM) configured to temporarily store data, and an electronic circuit such as a timer or the like. At least a part of the control device 10 is an integrated circuit such as a large scale integration (LSI) or the like.

The control device 10 includes, for example, a calculation part 10a, a first traveling controller 10b, and a second traveling controller 10c.

The calculation part 10a executes various types of calculation processing on the basis of information acquired from, for example, the driving operator 11, the vehicle sensor 12, the object detection device 13, the positioning signal receiver 14, the storage device 15, and the like.

Each of the first traveling controller 10b and the second traveling controller 10c controls the drive device 16, the brake device 17 and the steering device 18 to reduce an operating load of a driver during traveling of the vehicle 1.

The first traveling controller 10b controls driving assistance operations such as cruise control, lane keeping assistance, collision mitigation brake, and the like, for example, with a driver as a driving entity. The cruise control is controls, for example, fixed speed traveling of maintaining a speed of the vehicle 1 constantly, following traveling of maintaining an inter-vehicular distance between the vehicle 1 and a preceding vehicle constantly, and the like. The lane keeping assistance is, for example, control of assisting the vehicle 1 to travel a lane center. The collision mitigation brake is, for example, control of reducing a speed or stopping the vehicle through braking before a contact with an object, and supporting an avoidance action by steering.

The second traveling controller 10c reduces an operating load of the driver relatively more than the first traveling controller 10b. The second traveling controller 10c controls, for example, autonomous driving behavior that is not dependent on the driver, while not considering the driver to be the driving entity, so-called automatic driving.

For example, when each of the first traveling controller 10b and the second traveling controller 10c operates without regulation, power consumption of the second traveling controller 10c is relatively greater than power consumption of the first traveling controller 10b.

The driving operator 11 is an operator such as an accelerator pedal, a brake pedal, a shift lever, a steering wheel, or the like. The driving operator 11 includes, for example, a sensor configured to detect an operation amount of each operator or existence of the operation. Each sensor is, for example, an accelerator position sensor, a brake sensor, a steering sensor, or the like.

The accelerator position sensor detects, for example, an accelerator operation that is an accelerator position or the like varied according to an operation of the accelerator pedal (accelerator operator) by the driver of the vehicle 1, and outputs a detection signal of the accelerator operation.

The brake sensor is, for example, a fluid pressure sensor, a stroke sensor, or the like. The brake sensor detects, for example, a brake operation that is an operation of the brake pedal (brake operator) by the driver of the vehicle 1, a fluid pressure caused by the operation of the brake pedal, or the like, and outputs a detection signal of the brake operation.

The steering sensor is, for example, a torque sensor, a steering angle (rotation angle) sensor, or the like. The steering sensor detects, for example, a steering operation that is a torque, a steering angle, or the like, caused by the operation of the steering wheel (steering operator) by the driver of the vehicle 1, and outputs a detection signal of the steering operation.

The vehicle sensor 12 is a sensor configured to detect a state quantity related to a speed of the vehicle 1 such as a wheel speed sensor, a rotation number sensor, or the like, or a sensor configured to detect an inertial motion of the vehicle 1 such as an inertial measurement unit (IMU) or the like. The inertial motion of the vehicle 1 includes, for example, an acceleration detected by the acceleration sensor, an angular speed detected by a gyro sensor, and the like.

The object detection device 13 includes, for example, sonar, a radar device, a finder, a camera, and the like. The finder is, for example, light detection and ranging or laser imaging detection and ranging (LIDAR). The sonar, the radar device or the finder radiates, for example, ultrasonic waves, electromagnetic waves or light to the outside around the vehicle 1, and detects a distance to an object or a position of the object by detecting reflection or scattering by the object.

The camera is, for example, a digital camera including a solid-state imaging device such as a charge coupled device (CCD), a complementary metal oxide semiconductor (CMOS), or the like. The camera captures the outside of the vehicle 1 in, for example, a visible light range and an infrared light range and outputs the obtained image data.

The positioning signal receiver 14 includes, for example, an antenna for a global navigation satellite system (GNSS) such as a global positioning system (GPS) or the like. The positioning signal receiver 14 outputs information such as a position, a posture, and the like, of the vehicle 1 through predetermined calculation based on, for example, predetermined information or a positioning signal obtained from a positioning signal received by the antenna.

The storage device 15 stores, for example, map information. The map information includes, for example, information of a road shape by nodes and links, information of a road shape such as a number of lanes, a curvature, a width, a gradient, and the like, and information of a road structure such as a type, a position, an orientation, a size, and the like.

The drive device 16 includes, for example, a power source, a power transmission mechanism, a power controller, and the like. The power source is, for example, an electric motor, an internal combustion engine, and the like, that outputs power for traveling of the vehicle 1. The power transmission mechanism is, for example, a gearbox or the like that transmits power of the power source to driving wheels. The power controller is, for example, a power converter or the like that controls power transfer between the power supply and the electric motor. The drive device 16 controls, for example, power for traveling of the vehicle 1 according to an operation of the accelerator operator by the driver or a signal input from the control device 10.

The brake device 17 includes, for example, a braking mechanism such as a disk brake, a drum brake, or the like, using a fluid pressure such as a hydraulic pressure or the like, and an electric motor. The brake device 17 controls, for example, the electric motor according to an operation of the brake operator by the driver, a signal input from the control device 10, or the like, and outputs a brake torque to each of the wheels using a fluid pressure generated by the electric motor.

The steering device 18 includes, for example, a steering mechanism such as a rack and pinion mechanism or the like, and an electric motor. The steering device 18 controls, for example, the electric motor according to an operation of the steering operator by the driver, a signal or the like input from the control device 10, or the like, and changes a direction of the steered wheel.

FIG. 2 is a configuration view of a temperature control system 20 of the vehicle 1 of the embodiment.

As shown in FIG. 2, the temperature control system 20 includes, for example, a cooling circuit 21, a radiator (RAD) 22, a pump 23, and a drive unit (DU) 24.

The cooling circuit 21 is, for example, a cooling circuit of a drive train system.

The radiator 22 radiates heat from a thermal medium, for example, a so-called cooling water such as coolant or the like, distributed in the cooling circuit 21 through heat exchange with surrounding air, a cooling material, or the like.

The pump 23 is, for example, an electric water pump or the like. The pump 23 sends the thermal medium to the cooling circuit 21.

For example, the control device 10 and the drive unit 24 that constitutes a drive train are disposed in the cooling circuit 21 as a cooling target part of the vehicle 1.

The drive unit 24 is disposed, for example, downstream from the control device 10 in the cooling circuit 21. The drive unit 24 includes, for example, a rotating electric machine configured to give and receive a torque between left and right wheels, a differential mechanism configured to connect the rotating electric machine and the left and right wheels, and a power controller such as an inverter, a converter, or the like, configured to control power transfer with respect to the rotating electric machine.

Hereinafter, a control operation executed by the control device 10 of the vehicle 1 including the temperature control system 20 of the embodiment will be described.

The control device 10 regulates the output of the second traveling controller 10c according to the cooling load of the cooling target in the vehicle 1. The control device 10 regulates the output of the second traveling controller 10c, for example, when the cooling load of the cooling target other than the control device 10 is a predetermined load or more. The cooling target other than the control device 10 is, for example, a drive train of the vehicle 1.

The control device 10 controls a first state or a second state according to a traveling state of the vehicle 1, for example, when regulating the output of the second traveling controller 10c.

Each of the first state and second state is, for example, a state in which power consumption of the second traveling controller 10c is reduced.

The first state is, for example, a stopped state in which a power supply is off (no supply of electric power), a so-called shutdown state.

The second state is a state that has a greater processing load than the first state and resolves output reductions faster than the first state. The second state is, for example, a standby, pause or inhibit state after the power supply is turned on (electric power is being supplied), a so-called power saving state.

The control device 10 reduces the power consumption of the second traveling controller 10c in at least any one of the following cases: for example, when the vehicle 1 is traveling at a high speed equal to or higher than a predetermined speed on a highway; when the vehicle 1 is during towing traveling; or when the vehicle 1 is during climbing traveling.

For example, the control device 10 reduces the output of the second traveling controller 10c with the second state when the vehicle 1 is traveling on the highway.

For example, the control device 10 reduces the output of the second traveling controller 10c with the first state when the vehicle 1 is during towing traveling. For example, the control device 10 reduces the power consumption of the second traveling controller 10c with the second state when the vehicle 1 is high speed traveling at a predetermined speed or more, when the vehicle 1 is during towing traveling, or when the vehicle 1 is during climbing traveling.

For example, the control device 10 reduces the power consumption of the second traveling controller 10c with the first state in at least any two or more of the plurality of cases; when the vehicle 1 is high speed traveling at a predetermined speed or more, when the vehicle 1 is during towing traveling, or when the vehicle 1 is during climbing traveling.

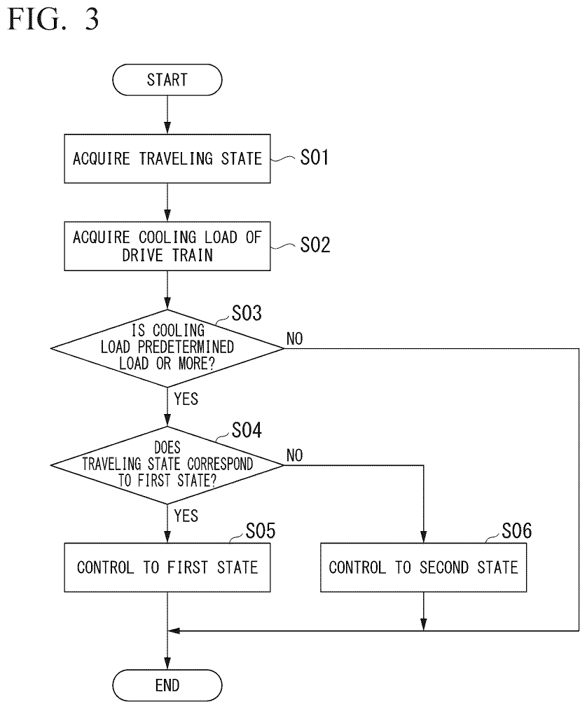

FIG. 3 is a flowchart showing an operation of the control device 10 of the vehicle 1 including the temperature control system 20 of the embodiment.

As shown in FIG. 3, first, the control device 10 acquires a traveling state of the vehicle 1 (step S01). The control device 10 acquires, for example, a traveling state of the vehicle 1 on the basis of the information acquired from the driving operator 11, the vehicle sensor 12, the object detection device 13, the positioning signal receiver 14, the storage device 15, and the like, and the information obtained from various types of calculation processing of the calculation part 10a. The traveling state of the vehicle 1 is, for example, when the vehicle 1 is high speed traveling at a predetermined speed or more on a highway or the like, when the vehicle 1 is during towing traveling, or when the vehicle 1 is during climbing traveling.

Next, the control device 10 acquires a cooling load of the drive train of the vehicle 1 (step S02).

Next, the control device 10 determines whether the cooling load of the drive train of the vehicle 1 is a predetermined load or more (step S03).

When the determination result is “NO,” the control device 10 advances the processing to end.

Meanwhile, when the determination result is “YES,” the control device 10 advances the processing to step S04.

Next, the control device 10 determines whether the traveling state of the vehicle 1 corresponds to the case in which the second traveling controller 10c is controlled in the first state (step S04).

When the determination result is “NO,” the control device 10 advances the processing to step S06.

Meanwhile, when the determination result is “YES,” the control device 10 advances the processing to step S05.

Next, the control device 10 controls the second traveling controller 10c to the first state (step S05). Then, the control device 10 advances the processing to end.

In addition, the control device 10 controls the second traveling controller 10c to the second state (step S06). Then, the control device 10 advances the processing to end.

As described above, according to the control device 10 of the vehicle 1 including the temperature control system 20 of the embodiment, when the cooling load of the cooling target part that is cooled by the cooling circuit 21 shared with the control device 10 is large, the output of the second traveling controller 10c, which has a relatively large processing load, is reduced. Accordingly, the cooling target part and the control device 10 can be cooled efficiently and continuously while suppressing the increase in size of the cooling circuit 21. By maintaining the output of the first traveling controller 10b, which has a relatively small processing load, the increase in the operating load of the driver can be suppressed. The traveling safety of the vehicle 1 can be appropriately ensured by continuously maintaining driving assistance operations such as following traveling, lane keeping and evasion assistance by the first traveling controller 10b.

The control device 10 can reduce the output of the second traveling controller 10c depending on whether it is the first state or the second state, which differ in the magnitude of the processing load and the speed at which the output reduction is resolved, and thus, the output of the second traveling controller 10c can be appropriately reduced according to the state of the vehicle 1.

The drive train and the control device 10, which require cooling while the vehicle 1 is traveling, can be cooled simultaneously by the common cooling circuit 21, and it is possible to suppress the complexity of the configuration of the cooling circuit 21 by cooling the drive train and the control device 10 simultaneously in series.

By reducing the output of the second traveling controller 10c when the cooling load of the drive train increases as the traveling load of the vehicle 1 increases, the drive train and the control device 10 can be efficiently and continuously cooled while suppressing the increase in size of the cooling circuit 21.

When the vehicle 1 is traveling on a highway, since the operational requirements of the second traveling controller 10c are higher, the operating load on the driver can be appropriately reduced by reducing the output of the second traveling controller 10c in the second state more than in the first state.

Since the towing of the vehicle 1 is unlikely to be released while traveling, and the traveling load and the cooling load of the control device 10 are unlikely to decrease while traveling, the control device 10 can be properly cooled by reducing the output of the second traveling controller 10c in the first state.

According to any one of case or any two or more of the cases of when the vehicle 1 is high speed traveling at a predetermined speed or more, when the vehicle 1 is during towing traveling and when the vehicle 1 is during climbing traveling, by selecting the second state or the first state, the output of the second traveling controller 10c can be reduced stepwise or otherwise depending on the magnitude of the traveling load of the vehicle 1 and the cooling load of the control device 10. When the cooling load of the control device 10 is relatively small, the second state can be used to prioritize the speed of resolving output reduction, and when the cooling load of the control device 10 is relatively large, the first state can be used to prioritize cooling.

### Variant

Hereinafter, a variant of the embodiment will be described. Further, the same parts as those in the embodiment described above will be designated by the same reference signs, and explanations thereof will be omitted or simplified.

In the above-mentioned embodiment, the control device 10 selects the second state when the vehicle 1 is traveling on a highway, but there is no limitation thereto. For example, when the vehicle 1 is traveling on a highway, the control device 10 may select the first state according to the magnitude of the traveling load and the processing load, while prioritizing the selection of the second state.

In the above-mentioned embodiment, the control device 10 may switch between the first state and the second state depending on the magnitude of the inclination angle while the vehicle 1 is during climbing traveling.

In the above-mentioned embodiment, while the cooling target part of the vehicle 1 is the drive train, there is no limitation thereto. For example, the cooling target part of the vehicle 1 may be at least one of the drive train and the power storage device such as a battery or the like installed in the vehicle 1.

While preferred embodiments of the invention have been described and illustrated above, it should be understood that these are exemplary of the invention and are not to be considered as limiting. Additions, omissions, substitutions, and other modifications can be made without departing from the scope of the present invention. Accordingly, the invention is not to be considered as being limited by the foregoing description, and is only limited by the scope of the appended claims.

What is claimed is:

1. A control device for a vehicle comprising a controller cooled together with a cooling target part by a cooling part of a vehicle,
wherein the controller includes:
a first controller configured to execute traveling control for reducing an operating load of a driver; and
a second controller configured to execute traveling control for reducing the operating load of the driver to a greater extent than in the first controller, and
wherein an output of the second controller is reduced when the cooling load of the cooling target part is a predetermined load or more.

2. The control device for a vehicle according to claim 1, wherein, when reducing the output of the second controller, the controller selects a first state or a second state which has a larger processing load than the first state and in which output reduction is resolved faster than in the first state.

3. The control device for a vehicle according to claim 1, wherein the controller and the cooling target part need to be cooled while the vehicle is traveling.

4. The control device for a vehicle according to claim 3, wherein the controller and the cooling target part are cooled in series by the cooling part.

5. The control device for a vehicle according to claim 1, wherein the cooling target part is a drive train of the vehicle.

6. The control device for a vehicle according to claim 3, wherein the controller reduces the output of the second controller in at least any one of the following cases: when the vehicle is traveling at high speed, when the vehicle is during towing traveling and when the vehicle is during climbing traveling.

7. The control device for a vehicle according to claim 6, wherein the controller reduces the output of the second controller with the second state when the vehicle is traveling on a highway.

8. The control device for a vehicle according to claim 6, wherein the controller reduces the output of the second controller with the first state when the vehicle is during towing traveling.

9. The control device for a vehicle according to claim 6, wherein the controller reduces the output of the second controller with the second state when the vehicle is high speed traveling, when the vehicle is during towing traveling or when the vehicle is during climbing traveling, and
wherein the controller reduces the output of the second controller with the first state in at least any two or more of a plurality of cases: when the vehicle is high speed traveling, when the vehicle is during towing traveling and when the vehicle is during climbing traveling.
